(19) United States
(12) Patent Application Publication
(10) Pub. No.: US 2011/0043986 A1
(43) Pub. Date: Feb. 24, 2011

(54) POWER SUPPLY ASSEMBLY FOR SERVER RACK AND METHOD FOR MOUNTING POWER SUPPLY FOR SERVER RACK

(76) Inventors: Kevin D. Conn, Montgomery, TX (US); David A. Selvidge, Cypress, TX (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/937,938

(22) PCT Filed: Apr. 30, 2008
(86) PCT No.: PCT/US08/62020

§ 371 Date: Oct. 14, 2010

(51) Int. Cl. H05K 7/00

(52) U.S. Cl. 361/679.02

(57) ABSTRACT

A power supply assembly for electronic components, such as servers, can include a power supply and a mount. The power supply is connected to the mount and is configured to power a plurality of electronic components. The power supply assembly can include a connection between the power supply and mount that is configured to permit the power supply to pivot about an axis in relation to the mount.

### BACKGROUND OF THE INVENTION

Server racks are often used to hold a multitude of electronic devices such as servers. The servers are generally stacked vertically and are disposed in slots in the server rack. Servers generally include one or more powered components and therefore include one or more power supplies to rectify, invert, adjust voltage, or otherwise alter an external power source, such as alternating current from a wall socket supplied by a utility, so that the external power source may be used by the various components. A power supply is typically integrated within each server, i.e., a single power supply is dedicated to a single server.

A high density rack (e.g., with a relatively large concentration of servers or other electronic devices) is generally desired. However, the size of the electronic devices, including size associated with their typically bulky power supplies, can utilize precious space in the rack that otherwise could be occupied by other devices or components.

### SUMMARY OF THE INVENTION

One embodiment of the invention relates to a power supply assembly for electronic components in a server rack. The power supply assembly can include a mount and a power supply connected to the mount. The power supply can be configured to power a plurality of electronic components.

Another embodiment of the invention relates to an electronic device system that includes a frame, a plurality of electronic components disposed on the frame, a mount, and a power supply connected to the mount. The power supply can be configured to power the plurality of electronic components.

Another aspect of the invention relates to a method of mounting a power supply for an electronic device system including a frame with a plurality of electronic components. The method can include the steps of connecting a mount to the frame, connecting a power supply to the mount to form the power supply assembly, and electrically connecting the power supply to the plurality of electronic components.

### BRIEF DESCRIPTION OF THE DRAWINGS

FIG. 1 is a rear isometric view of a server rack with a plurality of power supply assemblies, according to an embodiment.

FIG. 2 is an isometric view of a power supply assembly, according to an embodiment, with the power supply in a first position.

FIG. 3 is an isometric view of the power supply assembly of FIG. 2, with the power supply rotated to a second position.

FIG. 4 is an isometric view of a power supply assembly mount of the power supply of FIG. 2.

FIG. 5 is an isometric view of a bottom shelf or horizontal member of the power supply assembly mount of FIG. 4.

FIG. 6 is an isometric view of a left side bracket of the power supply assembly mount of FIG. 4.

FIG. 7 is an isometric view of a right side bracket of the power supply assembly mount of FIG. 4.

FIG. 8 is an enlarged view of the pivoting connection that connects the power supply to the power supply mount in the power supply assembly of FIG. 2.

FIG. 9 is a section view of the power supply and the shelf of the power supply assembly of FIG. 2.

### DETAILED DESCRIPTION OF THE PREFERRED EMBODIMENTS

Presently preferred embodiments of the invention are illustrated in the drawings. In the drawings, an effort has been made to use like numerals to represent like parts.

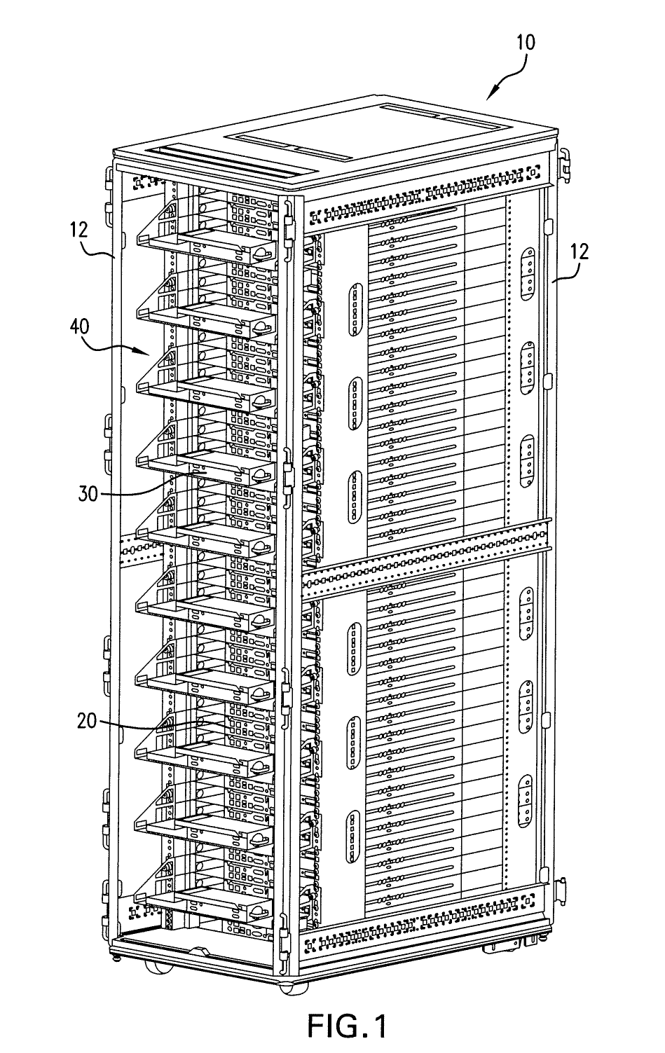

Referring to FIG. 1, an example of a server rack or frame 10 is shown. Frames 10, such as the one shown in FIG. 1, can be used to hold a multitude of electronic devices 20, such as, for example, servers. The frame 10 generally includes substantially vertical fixtures 12, such as metal strips or bars, that are spaced apart from one another. The electronic devices 20 may be coupled the frame 10 with a fastening device, such as, for example, a threaded bolt, a bolt and cage nut connector, a retention clip or hook, or other fastening devices known in the art. According to various examples, the electronic devices 20 may be coupled directly to the frame 10 or may be, coupled to rails that are, in turn, coupled to the frame 10 and allow the electronic device to be slid in and out of the frame 10. The frame 10 can have round holes, square holes, or holes of other shapes, as is known in the art.

Frames 10 generally are designed with receptacles (e.g., bays, slots or spaces) to receive an electronic device 20. Each receptacle can be referred to as a unit (U) and can, for example, divide the frame into a series of frame Us. Each U can have a size of, for example, 1.75 inches Electronic devices 20 coupled to the frames may be commonly configured as, for example, a storage blade module or other frame-mounted servers known in the art. The electronic devices 20 are generally designed to occupy a number of frame units (e.g., 1 U, 2 U, etc.).

The electronic devices 20 can include multiple components, some of which can be configured to be accessible via the front panel of the electronic device 20 and the front of the frame 10. The components are generally powered and may require a power supply 30 to rectify, invert, adjust voltage, or otherwise alter an external power source such as alternating current from a wall socket as supplied by a utility.

Rather than providing a power supply such that is integrated within an electronic device so that a single power supply is dedicated to a single electronic device in a one-for-one arrangement of power supply to electronic device, a power supply assembly 40 preferably can be structurally separate from any electronic device and/or arranged to power a plurality of electronic devices 20. For example, the power supply assembly 40 can be arranged to provide power to two, three, or four or more electronic devices 20 arranged in a frame 10. Consequently, the electronic devices 20 (without integrated power supplies) can be made smaller and permit an increase in rack density.

The power supply assembly 40 can be arranged within a space of a frame 10 so that the power supply assembly 40 does not utilize a large amount of space within the frame 10. Also, the power supply assembly 40 can be arranged so that it does not block access to electronic devices arranged within the frame 10. For example, the power supply assembly 40 can be arranged within a open space where electronic devices 20 are not located, such as, for example, on the front, side, or rear of a frame 10. As shown in the example of FIG. 1, a power supply assembly 40 can be arranged on the rear of a frame 10 so that the power supply assembly 40 powers a plurality of electronic components 20. In a further example, the power supply assembly 40 can be mounted on a rear surface of a frame 10 between the two rear vertical fixtures 12. The space in the rear of a frame 10 can be a volume of space that is generally occupied only by cables, such as the zero U space of a frame 10. Such an arrangement can provide a user with flexibility in providing various mounting configurations.

As shown in the example of FIG. 1, a power supply assembly 40 can occupy 2 U of space (approximately 3.5 inches) in the rear of a frame 10. The use of the power supply assembly 40 provides an expandable, adaptable system where more or fewer power supplies 30 may be added to power various electronic devices 20. The power supply assembly 40 is configured to provide power to one or more electronic components. By consolidating the power supplies 30 for one or more electronic devices 20, less space is needed within the frame 10 for power supplies, allowing more room for other components and providing improved access to the electronic components. The power supply assembly 40 is designed to be a relatively low-cost mechanism for mounting power supplies 30 to a frame 10. By providing a single power supply 30 for multiple electronic devices 20, mounts 40 may be coupled to the frame 10, such as a rear of the frame 10, without intruding on the interior space of the frame 10 necessary for components of the electronic devices 20.

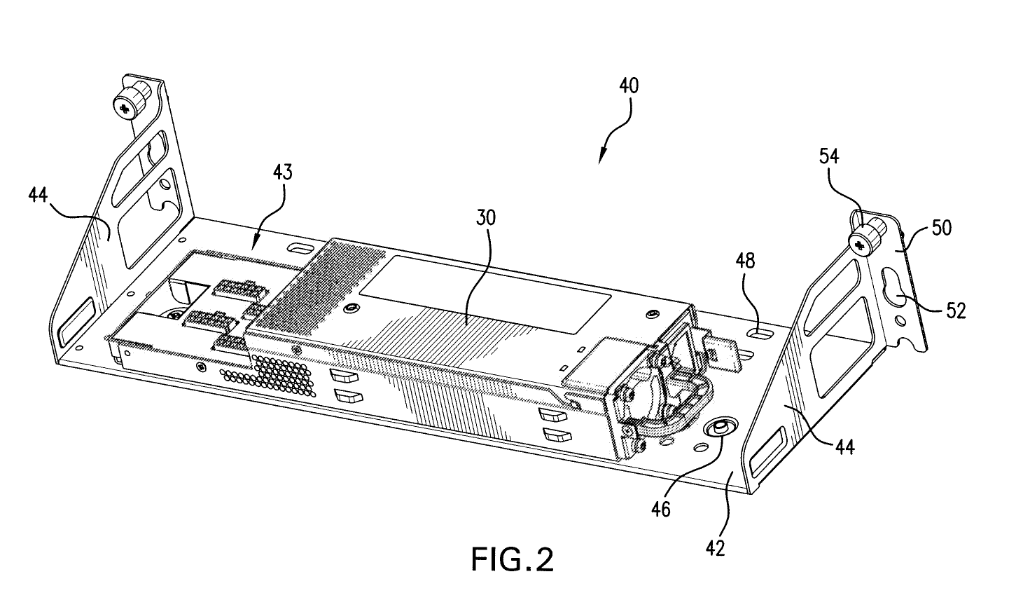

Referring now to FIG. 2, a power supply assembly 40 is shown according to an exemplary embodiment. The power supply assembly can include a power supply 30 (formed in a manner that will be known to one skilled in the art upon reading this disclosure) that is coupled to a mount or carrier 43. The power supply 30 is disposed in a first position in FIG. 2. As shown in the example of FIG. 2, the mount 43 can have a substantially U-shaped body with a base, shelf or horizontal member 42 that supports the power supply 30, and two vertical side walls or brackets 44 that are coupled to the shelf 42.

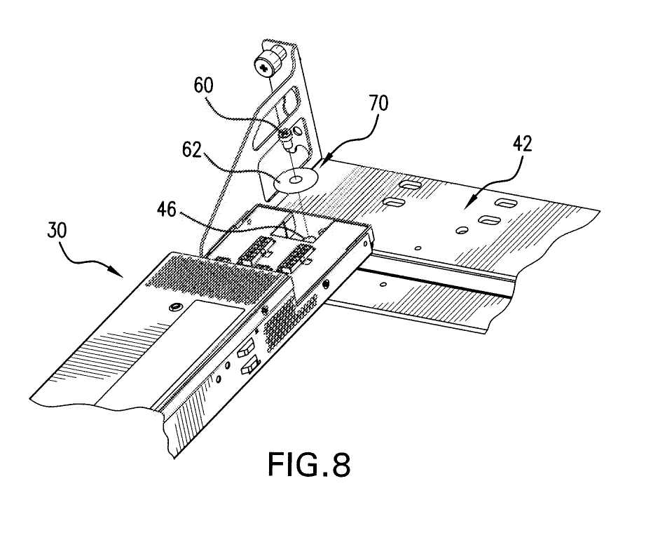

The shelf 42 can include one or more connection points 46 for mounting the power supply 30 to the mount 43. A connection point 46 can be, for example, a hole in the shelf 42, a bracket, or other joining device used in the art. As shown in the example of FIG. 8, the power supply 30 can be connected to the shelf 42 by a first connection that is configured to permit the power supply to pivot about an axis in relation to the mount, such as a bolt 62 that extends through the connection point 46 or hole. The connection can further include a washer 62, as shown in the example of FIG. 8. A standard T-25 screwdriver or a flat-headed screwdriver can be used to form such a connection. According to another example, the power supply 30 can be connected to the mount 43 with slotted screws or any other suitable fastener.

Because the power supply 30 is provided in the area behind the electronic devices 20 that is generally occupied by cables, the power supply may be disposed in a middle area of the shelf 42 or to one side of the shelf 42, such as closer to one of the brackets 44 to provide space for the cables. The shelf 42 may include multiple openings so the power supply may be located at various places along the shelf depending on the routing of the cables for the electronic devices 20. The shelf 42 can further include slots 48 or other suitable openings that are configured to allow cables to pass through the shelf 42.

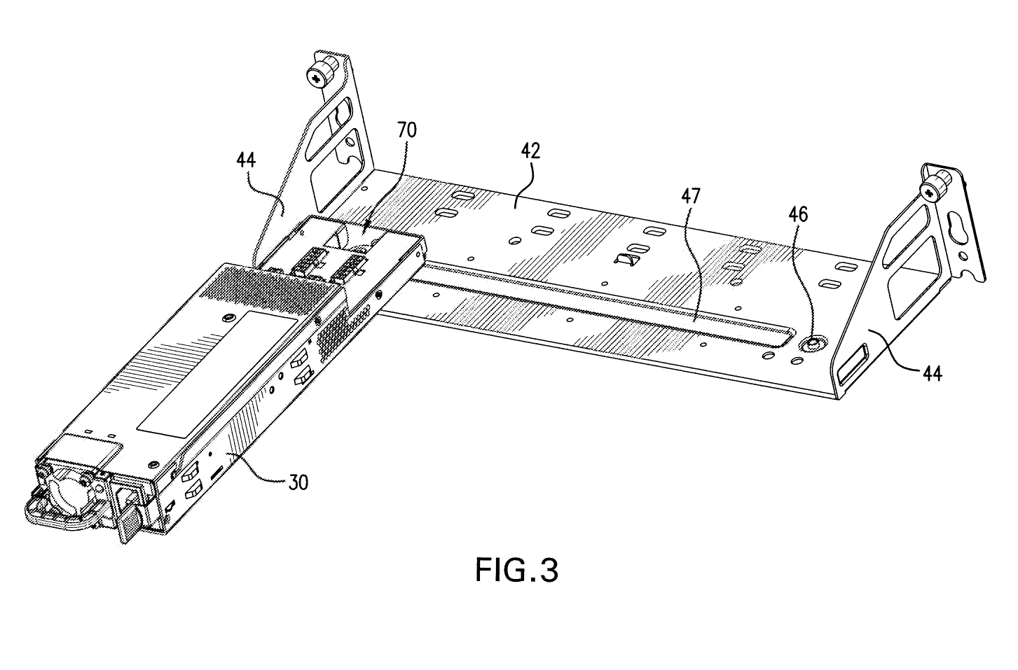

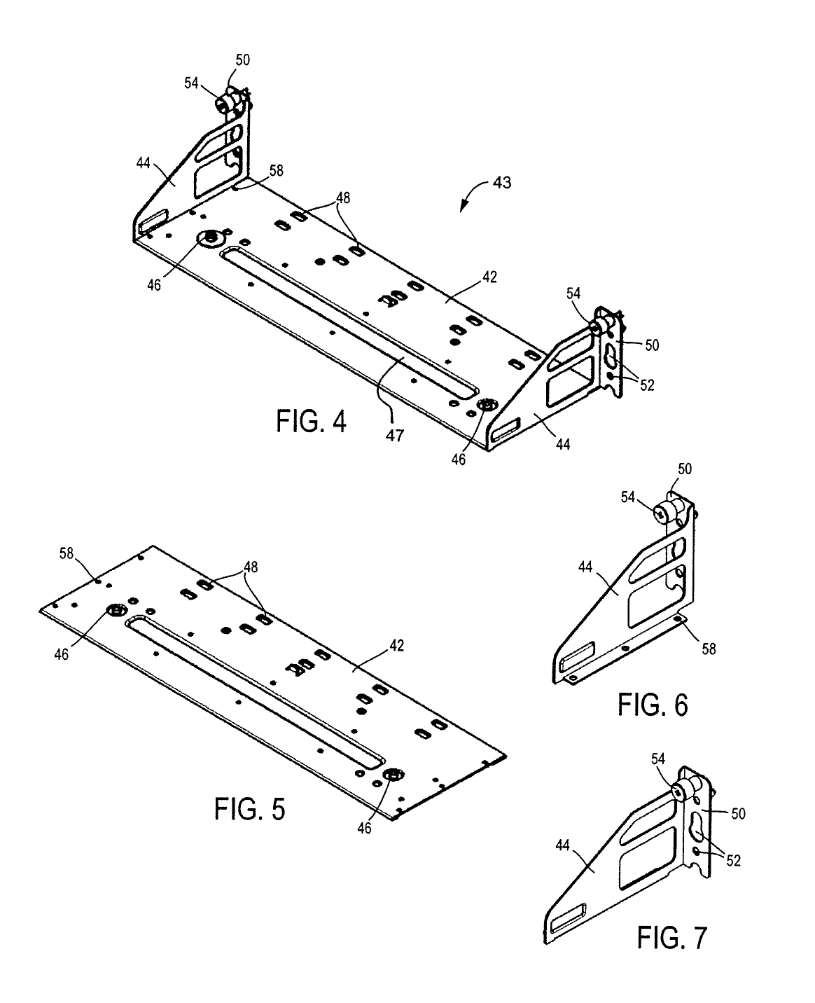

According to an example, at least one of the connections formed at a connection point 46 coupling the power supply 30 to the mount 43 can be configured so that the connection provides a connection between the power supply 30 and the mount 43 that permits the power supply 30 to pivot about an axis in relation to the mount 43. For example, as shown in FIG. 3, a connection 70 formed at a connection point 46 disposed, for example, near a first end of the power supply can be configured so that the power supply 30 can be rotated about an axis defined by the connection 70. As shown in the example of FIG. 4, the connection 70 can be disposed on a left side of the mount 43 or a right side of the mount 43 due to the presence of connection points 46 at the left side and right side of the mount 43. FIG. 8 shows an exploded view of the exemplary pivoting connection 70 shown in FIG. 3. The pivoting connection 70 can be formed by a screw 60 or other fastener that is joined to a connection point 46, such as, for example, a hole. The pivoting connection 70 can further include a washer 62. Such a pivoting connection 70 can permit a power supply 30 to pivot about an axis in relation to a mount 43 from a first mounted position, as shown in the example of FIG. 2, to a second mounted position, as shown in the example of FIG. 3. As discussed in the examples above, the pivoting connection 70 can be formed using a standard T-25 screwdriver or a flat-headed screwdriver. According to another example, the pivoting connection 70 can be made with slotted screws or any other suitable fastener.

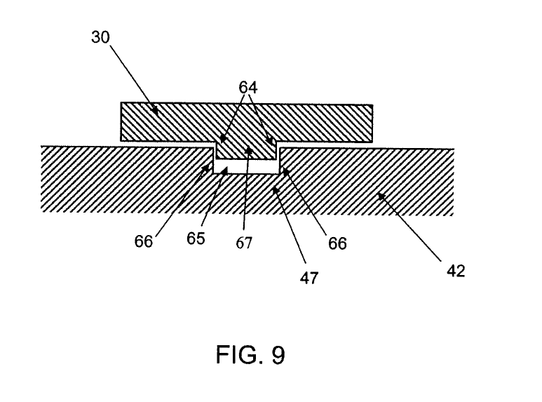

A second connection 47 disposed, for example, near a second end of the power supply can be configured to releasably couple the power supply 30 to the mount 43. FIG. 9 shows a sectional view of a power supply 30 and a shelf 42, according to an example. As shown in FIG. 9, the releasable connection 47 can be formed by a recess 65 formed in the shelf 42 and a projection 67 formed on the power supply 30. The power supply 30 can be securely held in place by the releasable connection 47 when the projection 67 is placed within the recess 65. For example, the projection 67 can be placed within the recess 65 when the power supply 30 and shelf 42 are positioned in relation to one another as shown in the example of FIG. 2. The projection 67 can be configured to releasably engage with the recess 65 so that when a force sufficient to overcome the releasable connection 47 is applied the projection 67 and recess 65 disengage from one another, permitting the power supply 30 and mount 43 to move relative to one another, such as via the pivoting connection 70. According to a further example, the projection 67 can include sidewalls 64 that are configured to engage with sidewalls 66 of the recess 65. The sidewalls 64, 66 can have sharp corners, as shown in the example of FIG. 9, or the sidewalls 64, 66 can form corners with a rounded shape or other shape. The shape and size of the projection 67 and/or recess 65 (including sidewalls 64, 66) can be designed to affect the amount of force necessary to overcome the releasable connection 47. For example, a larger projection 67 and/or recess 65 can be provided to require a larger amount of force necessary to overcome the releasable connection 47.

By providing such a releasable connection 47, the power supply 30 can be securely held in place on the mount 43 in a first position (as shown in the example of FIG. 2) and, upon releasing the releasable connection 47 at the second end of the power supply 30, can be rotated to a second position (as shown in the example of FIG. 3). For example, the releasable connection 47 can be configured to maintain the power supply 30 in place relative to the mount 43 until a user applies a force sufficient to overcome the releasable connection. Such a releasable connection can be configured to release when the power supply 30 is pivoted about the axis of the pivoting connection 46 in relation to the mount 43. According to a further example, such a releasable connection can be formed by, for example, a force fit between the power supply 30 and the mount 43, a snap connection, or other suitable releasable connections.

Such a configuration in which the power supply 30 can rotate relative to the mount 43 permits a user to easily access the space located between the power supply 30 and the electronic devices 20 powered by the power supply. For example, the rotation of the power supply 30 can be used to access the electronic devices and/or any cables normally located between the power supply 30 and the electronic devices 20 in a frame 10.

Brackets 44 can be configured to extend generally perpendicular to the shelf 42 and to couple the shelf 42 to a frame 10. The brackets 44 can include flanges 50 that are spaced apart from each other such that they align with the vertical fixtures 12 of the frame 10. Each flange 50 can include one or more openings 52 for fasteners to couple the power supply assembly 40 to the frame 10. The openings 52 may be generally circular, rectangular, elongated slots, or have other shapes as is known in the art. According to an example, captured, floating thumb screws 54 can be used to couple the power supply assembly 40 to a frame 10 so that power supply assembly 40 may be attached to the frame 10 without the necessity of any additional tools. According to another example, the power supply assembly 40 can be coupled to the frame 10 through the use of other fasteners known in the art, such as, for example, a retention clip or hook.

According to an example, the shelf 42 and the brackets 44 can be formed as separate pieces, as shown in FIGS. 5-7. Shelf 42 may be formed, for example, from sheet metal such as 16 gauge galvanized steel or other suitable material. According to this example, the shelf 42 and brackets 44 can include corresponding openings 58 for coupling together the shelf 42 and brackets 44 with rivets, screws, or other suitable fasteners. According to other exemplary embodiments, the shelf 42 and the brackets 44 may be joined together via a joining method such as welding, brazing, adhesives, or other joining methods known in the art. According to still other exemplary embodiments, the shelf 42 and brackets 44 may be formed as a single body of unitary, single-piece construction.

The foregoing description of embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principals of the invention and its practical application to enable one skilled in the art to utilize the invention in various embodiments and with various modifications as are suited to the particular use contemplated. Other embodiments of the invention will be apparent to those skilled in the art from consideration of the specification and practice of the invention disclosed herein.

What is claimed is:

1. A power supply assembly for electronic components in a server rack, comprising:
a mount; and
a power supply connected to the mount, wherein the power supply is configured to power a plurality of electronic components.

2. The power supply assembly of claim 1, wherein the power supply assembly is configured to be mounted on a rear surface of a frame of the server rack containing the plurality of electronic components.

3. The power supply assembly of claim 2, wherein the electronic components are servers.

4. The power supply assembly of claim 1, wherein the connection of the power supply to the mount includes a first connection that is configured to permit the power supply to pivot about an axis in relation to the mount.

5. The power supply assembly of claim 4, wherein the connection of the power supply to the mount further includes a second connection that is releasable, wherein the second connection is configured to release when the power supply is pivoted about the axis in relation to the mount via the first connection.

6. The power supply assembly of claim 1, wherein the mount includes a base, wherein the power supply is connected to the base.

7. The power supply assembly of claim 6, wherein the mount further includes at least one side bracket configured to be mounted to a frame of the server rack.

8. The power supply assembly of claim 1, wherein the power supply assembly includes slots for receiving cables.

9. The power supply assembly of claim 1, wherein the power supply assembly is configured to be disposed away from the electronic components and configured to be electrically connected to the electronic components.

10. An electronic device system, comprising:
a frame;
a plurality of electronic components disposed on the frame;
a mount; and
a power supply connected to the mount, wherein the power supply is configured to power the plurality of electronic components.

11. The electronic device system of claim 10, wherein the mount is mounted on a rear surface of the frame.

12. The electronic device system of claim 10, wherein the electronic components are servers.

13. The electronic device system of claim 10, wherein the connection of the power supply to the mount includes a first connection that is configured to permit the power supply to pivot about an axis in relation to the mount.

14. The electronic device system of claim 13, wherein the connection of the power supply to the mount further includes a second connection that is releasable, wherein the second connection is configured to release when the power supply is pivoted about the axis in relation to the mount via the first connection.

15. The electronic device system of claim 10, wherein the mount includes a base, wherein the power supply is connected to the base.

16. The electronic device system of claim 15, wherein the mount further includes at least one side bracket configured to be mounted to the frame.

17. The electronic device system of claim 10, wherein the mount includes slots that receive cables.

18. The electronic device system of claim 10, wherein the power supply is disposed away from the electronic components and electrically connected to the electronic components.

19. A method of mounting a power supply for an electronic device system including a frame with a plurality of electronic components, comprising the steps of:
connecting a mount to the frame;
connecting a power supply to the mount to form the power supply assembly, and
electrically connecting the power supply to the plurality of electronic components.

20. The method of mounting a power supply of claim 19, wherein the mount is connected to a rear surface of the frame.

21. The method of mounting a power supply of claim 19, wherein the electronic components are servers.

22. The method of mounting a power supply of claim 19, wherein the power supply is connected to the mount by a first connection that is configured to permit the power supply to pivot about an axis in relation to the mount.

23. The method of mounting a power supply of claim 22, wherein the power supply is connected to the mount by a second connection that is releasable, wherein the second connection is configured to release when the power supply is pivoted about the axis in relation to the mount via the first connection.

24. The method of mounting a power supply of claim 10, wherein the power supply is disposed away from the electronic components and electrically connected to the electronic components.
